(19) United States
(12) Patent Application Publication
(10) Pub. No.: US 2008/0113456 A1
(43) Pub. Date: May 15, 2008

(54) PROCESS FOR PROTECTING IMAGE SENSOR WAFERS FROM FRONT SURFACE DAMAGE AND CONTAMINATION

(75) Inventors: Steven R. Codding, Underhill Center, VT (US); Timothy C. Krywanczyk, Essex Junction, VT (US); Robert K. Leidy, Burlington, VT (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/559,983

(22) Filed: Nov. 15, 2006

(51) Int. Cl. H01L 31/18

(52) U.S. Cl. 438/14; 257/E31.084

(57) ABSTRACT

A method for protecting a semiconductor wafer fabricated for image sensing operation from contamination and/or physical damage to a front wafer surface during post-fabrication processing. The method includes applying a protective tape layer on the front surface of the semiconductor wafer in order to protect active light sensors fabricated thereon.

### BACKGROUND OF THE INVENTION

1. Field of the Invention

The present invention relates to semiconductor image sensors. More particularly, the inventions described and claimed herein relate to a method for protecting a front surface of a semiconductor image sensor by application of a protective tape layer to prevent contamination and surface damage during testing, transport, storage and dicing and picking.

2. Description of the Related Art

Semiconductor fabrication processes are well established. In semiconductor fabrication, semiconductor wafers are modified and transformed in a series of multiple processing steps to create desirable features on the finished semiconductor chip or finished module. Inage sensors are semiconductor chips fabricated to receive and capture light image information (e.g., intensity information) and directly convert the captured light information to form a digital image. Image sensors are classified as charge-coupled devices (CCDs) and complimentary metal oxide semiconductor (CMOS) devices. CCD image sensors capture light onto an array of light sensitive diodes, where each diode represents a pixel. The pixel converts the light photons into commensurate electric charge, which is accumulated by a charge-coupling operation to generate each pixel's signal. CMOS image sensors, like CCD image sensors, include an array of photosensitive diodes, with one diode allocated for each pixel. They differ however in that each CMOS-based pixel includes its own amplifier and may be read directly on an x-y coordinate system rather than by the charge-coupling process required by CCD-based image sensors.

The reader should note that the percentage of a pixel area on the active wafer surface that actually captures light is called the pixel “fill factor.” This light capturing or active area is typically about 40% of the allocated pixel surface area. The remainder of the allocated pixel area surface is used for various purposes known to the skilled artisan. In some image sensor pixel designs, the fill factor is too small to be effective for particular imaging applications. To accommodate this problem, the image sensor allocated pixel area surface may include small lenses (i.e., microlenses) formed directly above each pixel. The microlens focuses the incident light received at the pixel area towards the active area or light-capturing portion of the allocated pixel surface area. This effectively increases the fill factor, for example, up to three (3) times.

Because the active or light-capturing portion of each pixel's allocated surface area (with or without microlenses) is light responsive, it follows that pixel operation is extremely sensitive to contamination, e.g., dust particles that may accumulate thereon, and surface damage such as scratching which may occur in various post-fabrication handling processes. The contamination and damage may block or limit accurate capture of the light incident on affected pixel areas. That is, contamination particles can block or modify incident light received thereon and sensed by the photodiodes comprising the image sensor. This can cause the individual sensors to fail testing, and may show up in an image acquired by a damaged or contaminated image sensor that nevertheless passes testing. Conventionally, image sensor fabrication and post-fabrication processes are carried out in clean rooms, or under clean room conditions to avoid contamination by dust and other debris. To avoid damaging the front surfaces with or without microlenses, finished wafers are stacked (stored) and transported using crystal packs, which increase manufacturing cost.

Since wafer test assembly areas are typically not controlled to the same standards maintained within cleanrooms for wafer fabrication, contamination of image sensor wafers is a key challenge to high yield manufacturing. For that matter, wafer testing may generate contamination such aluminum (Al) particles that are scraped up by probe needles, picked up and deposited elsewhere on the active or front surface. Image sensors comprising sensitive microlens structures on the active or front surfaces are easily damaged during pre-assembly handling, storage and shipping between wafer fabrication and assembly locations. For that matter, merely stacking the image sensor wafers between processes can damage very sensitive microlenses. Accordingly, it would be a welcomed addition to image sensor manufacturing to realize a inexpensive, convenient and effective way of protecting the active or front surface of image sensors, post-fabrication through module of image sensor chip form.

### SUMMARY OF THE INVENTION

To that end, the inventions described and set forth herein include a method for protecting the front or active surfaces of image sensor wafers in order to protect the active sensor surfaces from debris accumulation and/or physical damage post-fabrication.

In one embodiment, the inventive method includes applying a protective layer in a form of a protective tape on the active or front surface of the fabricated image sensor wafer. The protective tape is preferably a “zero-washing” tape. Various tapes that are normally used during fabrication may be used in the inventive method for post-fabrication protection of image sensor wafers. For example, back-grinding tapes that are normally used for application to a backside of a semiconductor wafer during grinding processes will effectively protect and are readily peeled. Protective tapes are preferably light transparent to facilitate inspection. Semiconductor image sensor wafers with a protective back-grinding tape applied to the active or front wafer surface allows for the wafers to be tested, stored, further processed (e.g., cut and diced), or transported to other locations for further processing without front surface damage, or accumulated contamination that might otherwise affect sensor operation. That is, debris generated from the wafer testing, dust particles and the like accumulates on the protective tape layer rather than being deposited on the active sensor surface. After dicing and assembly to module form, the film is merely peeled off the active light-capturing surfaces.

Accordingly, the active image sensor surface and/or microlens structures are protected, increasing yield and therefore lowering overall image sensor manufacturing cost. In addition, the protective tape provides that the stringency of clean room requirements may be reduced as well, still further reducing manufacturing cost.

### BRIEF DESCRIPTION OF THE DRAWINGS

The foregoing and other objects, aspects and advantages will be better understood from the following detailed description of embodiments of the inventions, with reference to the drawings, in which:

FIG. 1 shows a semiconductor wafer comprising one or more image sensors as the protective tape is applied by the inventive process; and

FIG. 2 depicts a schematic block diagram of a method for protecting a semiconductor image sensor wafer of this invention.

### DETAILED DESCRIPTION OF THE INVENTION

The inventive method for protecting semiconductor image sensor wafers for post fabrication processing as set forth and described herein is disclosed for the purpose of conveying the broad inventive concept. In particular, the drawings and descriptions provided are not meant to limit the scope and spirit of the invention in any way as claimed in the claim set appended hereto. To that end, reference will now be made in detail to the present invention, examples of which are illustrated in the accompanying drawings, wherein like reference numerals refer to like elements throughout.

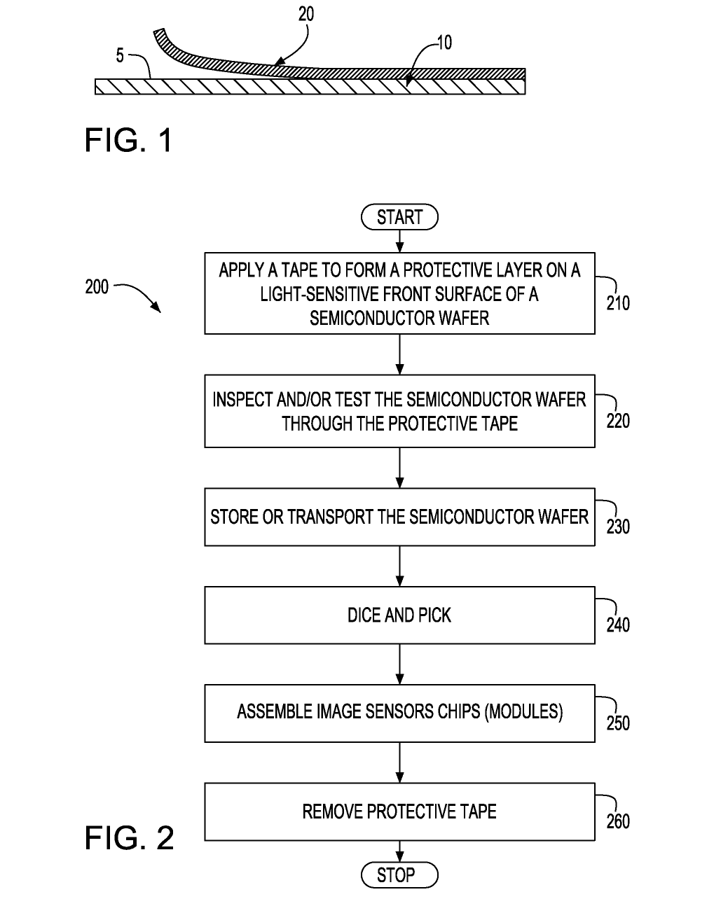

The reader's attention is first directed to FIG. 1, which depicts one embodiment of a method for protecting an active surface 5 of a semiconductor wafer 10 fabricated for image sensor chip manufacture. The inventive method includes applying a protective layer of tape 20 to the front or active surface 5 of the semiconductor wafer 10. The tape may be one of pressure sensitive or photosensitive. In the case where the tape is photosensitive, the tape is removed by exposing the front surface upon which the photosensitive tape is adhered to ultra-violet light.

Various sources and methods for applying the protective tapes are known from conventional use in semiconductor fabrication processes, e.g., back-grinding tape applied by a roller tape system. Disco, Inc., Nitto Denko, Inc., STM, Inc and 3M Company are just a few. The tape should readily peal from the protected surface (e.g., zero-wash tape), and be transparent to facilitate inspection and testing. As already mentioned, the protective tape may be pressure sensitive (PST) or photosensitive. Where the tape is photo- or UV-sensitive, tape removal may require deactivation with the electromagnetic radiation to which the UV tape is responsive.

The benefits to semiconductor manufacturers who utilize the inventive method are many. For example, the image sensor wafers protected by the inventive method may thereafter be tested, stored, transported, diced and picked and packaged before the protective tape layer is removed. Because the semiconductor wafer 10 is an image sensor, it may contain thousands of fabricated pixels or die, where the fabricated pixels (not shown in detail) may include microlenses to focus light striking the entire pixel area to the active portion pixel area. Once the semiconductor wafer is protected by the tape, the image sensor pixels may be tested without concern for contamination or scratching of the protected image sensor surface. Testing may be carried out with automatic or manual test equipment.

The protected image sensor wafer may be stored without damaging to the image sensing surfaces. For that matter, the protected wafers may be transported after testing to an external assembly location without conventional risk of contaminating or physically damaging the active image sensor surface in view of the protective layer. Transport may be accomplished more efficiently because the wafers may be arranged for storage in simple coin stacks, rather than protective crystal packs required for wafers that are not protected at their active or front surfaces.

The protected image sensor wafer may be diced and picked at any location available that is convenient. That is, dicing and assembly may be carried out at a clean room facility, or at a manufacturing facility where less critical environmental controls are in place. The result is an image sensor chip or module where the image capture or light sensitive pixel surface portions are contamination and damage free.

FIG. 2 is a flow block diagram that depicts a method 200 for protecting a semiconductor wafer fabricated for image sensing operation. Block 210 represents a step of applying a protective layer of either UV-sensitive or pressure sensitive tapes, such as known back-grinding tape, to the entire light-sensitive front surface of the semiconductor wafer after fabrication. The tape is preferably rolled on the entire front surface of the image sensor wafer by known tape application processes and systems without deviating from the scope and spirit of the invention. Block 220 represents a step of testing the semiconductor wafer through the protective tape layer after the protective tape is applied to the wafer front surface.

Block 230 represents a step of transporting, or storing the protected semiconductor wafers. That is, with tape adhered to the front surface of the fabricated image sensor wafers, the wafers are more conveniently stored due to the protection of the front surface, and much less likely to be damaged during storage and handling. Block 240 represents a step of dicing the semiconductor wafer, and block 250 represents a step of assembling one or more image sensing chips from the diced portions. Block 260 represents a step of removing the protective tape from the image sensing chips.

In the method 200, the semiconductor wafer may be fabricated using charge coupled device (CCD) technology, or complimentary metal oxide semiconductor (CMOS) technology, and preferably include microlens structures to improve the quality of the finished module light sensor operation. The skilled semiconductor practitioners should understand that while the exemplary method and computer readable medium that embodies the method in a set of computer-readable and computer-implementable instructions calls out tape removal at the end of the various handling, storage, inspection of the semiconductor wafers and image sensing devices, the method includes removing, and re-applying the tape at any point in the inventive method to better facilitate intended protection, without deviating from the scope and spirit of the invention.

Although a few examples of the present invention have been shown and described, it would be appreciated by those skilled in the art that changes may be made in these embodiments without departing from the principles and spirit of the invention, the scope of which is defined in the claims and their equivalents.

What is claimed is:

1. A method for protecting a semiconductor wafer fabricated for image sensing operation from contamination and/or physical damage to a front wafer surface during post-fabrication processing, the method comprising the steps of:
applying a protective tape layer on the front surface of the semiconductor wafer in order to protect active light sensors fabricated thereon.

2. The method for protecting as set forth in claim 1, wherein the step of applying includes rolling one of a pressure sensitive tape (PST) or a photosensitive tape (UV) onto the entire front surface of the front wafer surface.

3. The method for protecting as set forth in claim 1, further comprising storing the semiconductor wafer with the protective tape layer applied.

4. The method for protecting as set forth in claim 1, further comprising a step of testing the semiconductor wafer through the protective layer.

5. The method for protecting as set forth in claim 4, wherein tested semiconductor wafers are transported to a remote assembly location with the protective tape layer applied.

6. The method for protecting as set forth in claim 5, further comprising a step of dicing the protected semiconductor wafer at the remote location with the protective tape layer applied.

7. The method for protecting as set forth in claim 6, further comprising a step of assembling the protected semiconductor wafer at the remote location with the protective tape layer applied.

8. The method for protecting as set forth in claim 1, wherein the semiconductor wafer is fabricated using charge coupled device (CCD) technology.

9. The method for protecting as set forth in claim 1, wherein the semiconductor wafer is fabricated using complimentary metal oxide semiconductor (CMOS) technology.

10. A computer-readable medium that contains a plurality of computer readable instructions, which computer readable instructions are executable by a processor to carry out a method for protecting a semiconductor wafer fabricated for image sensing operation, the method comprising the steps of:
applying a protective tape layer on a light-sensitive front surface of the semiconductor wafer to prevent contamination and handling damage on the front surface.
